(19) United States
(12) Patent Application Publication
(10) Pub. No.: US 2026/0073961 A1
(43) Pub. Date: Mar. 12, 2026

(54) MAGNETIC MEMORY DEVICE

(71) Applicant: Kioxia Corporation, Tokyo (JP)

(72) Inventor: Kuniaki SUGIURA, Seoul (KR)

(73) Assignee: Kioxia Corporation, Tokyo (JP)

(21) Appl. No.: 19/074,682

(22) Filed: Mar. 10, 2025

(30) Foreign Application Priority Data
Sep. 10, 2024 (JP) 2024-156653

(51) Int. Cl. G11C 11/16

(52) U.S. Cl. CPC G11C 11/1673; G11C 11/1677; G11C 11/1693

(57) ABSTRACT

According to one embodiment, a magnetic memory device includes a memory cell, a current source, first to third switches, a detection circuit and a sense amplifier. The memory cell includes a variable resistance element and a selector element. The current source supplies a first current to the memory cell. The first switch is coupled between the memory cell and the current source. The second switch is coupled between the memory cell and a ground voltage node. The detection circuit includes a comparator and a diode. A first voltage charged to the memory cell is input to a first input terminal of the comparator via the diode, and the first voltage is input to a second input terminal of the comparator. The sense amplifier compares the first voltage charged to the memory cell and a second voltage. The third switch is coupled between the memory cell and the sense amplifier.

### CROSS-REFERENCE TO RELATED APPLICATIONS

This application is based upon and claims the benefit of priority from Japanese Patent Application No. 2024-156653, filed Sep. 10, 2024, the entire contents of which are incorporated herein by reference.

### FIELD

Embodiments described herein relate generally to a magnetic memory device.

### BACKGROUND

A magnetic memory device that uses a magnetoresistive effect element as a memory element (MRAM: magnetoresistive random access memory) is known in the art.

### BRIEF DESCRIPTION OF THE DRAWINGS

FIG. 1 is a block diagram showing the configuration of a memory system including a magnetic memory device according to a first embodiment.

FIG. 2 is a circuit diagram showing the configuration of a memory cell array provided in the magnetic memory device according to the first embodiment.

FIG. 3 is a perspective view showing the structure of the memory cell array provided in the magnetic memory device according to the first embodiment.

FIG. 4 is a cross-sectional view of a memory cell in the memory cell array according to the first embodiment.

FIG. 5 is a circuit diagram showing the configuration of a read circuit provided in the magnetic memory device according to the first embodiment.

FIG. 6 is a graph showing the current-voltage characteristics of the snapback characteristic of a selector element according to the first embodiment.

FIG. 7 is a circuit diagram showing an example of the configuration of a delay circuit according to the first embodiment.

FIG. 8 is a graph showing voltage changes in the memory cell voltage and the diode voltage in a read operation according to the first embodiment.

FIG. 9 is a flowchart showing the flow of the read operation according to the first embodiment.

FIGS. 10 to 13 are diagrams showing switch states, a current flow, and a voltage change in the read operation according to the first embodiment.

FIG. 14 is a circuit diagram showing a configuration of a read circuit according to a second embodiment.

FIG. 15 is a circuit diagram showing a configuration of a read circuit according to a modification of the second embodiment.

FIG. 16 is a graph showing voltage changes in the memory cell voltage and the diode voltage in a read operation according to the modification of the second embodiment.

### DETAILED DESCRIPTION

In general, according to one embodiment, a magnetic memory device includes a memory cell, a current source, a first switch, a second switch, a detection circuit, a sense amplifier, and a third switch. The memory cell includes a variable resistance element and a selector element. The current source is configured to supply a first current to the memory cell. The first switch is coupled between the memory cell and the current source. The second switch is coupled between the memory cell and a ground voltage node to which a ground voltage is supplied. The detection circuit includes a comparator and a diode. A first voltage charged to the memory cell is input to a first input terminal of the comparator via the diode, and the first voltage is input to a second input terminal of the comparator. The sense amplifier is configured to compare the first voltage charged to the memory cell and a second voltage. The third switch is coupled between the memory cell and the sense amplifier.

Embodiments will be described with reference to the accompanying drawings. In the descriptions below, components having similar functions and configurations will be denoted by the same reference symbols. The embodiments described below merely show an exemplary apparatus and method that implement the technical ideas of the embodiments. The technical ideas are not limited to the element materials, shapes, structures, arrangements etc. described below.

### 1. FIRST EMBODIMENT

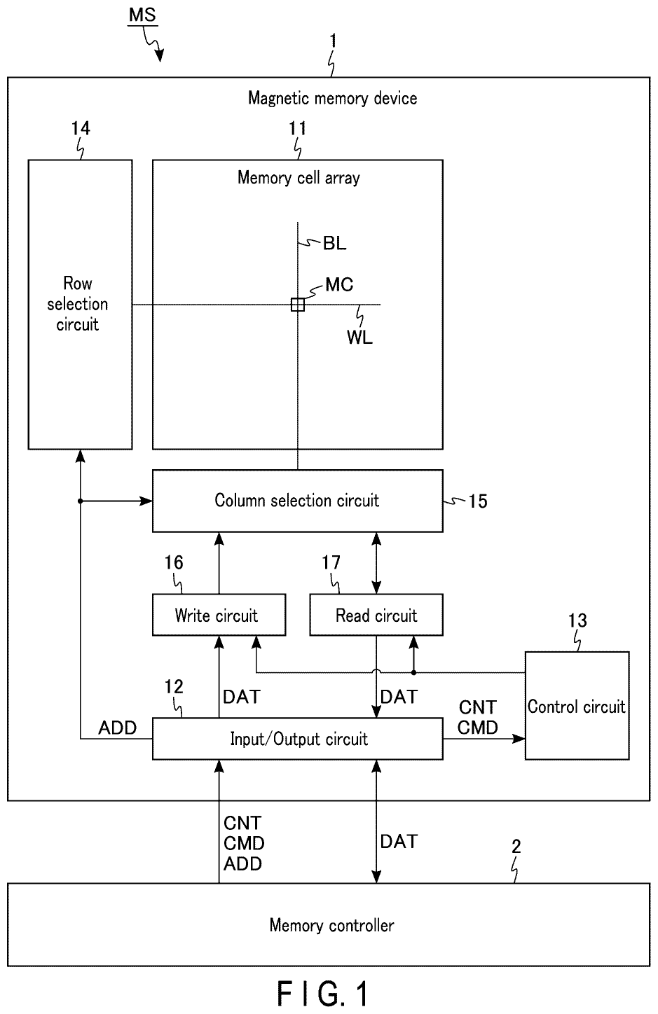

First, an example of a memory system including a magnetic memory device of a first embodiment will be described. FIG. 1 is a block diagram showing the configuration of the memory system MS including the magnetic memory device of the first embodiment.

As shown in FIG. 1, the memory system MS includes a memory controller 2 as well as the magnetic memory device 1. The magnetic memory device 1 operates under the control of the memory controller 2. The memory controller 2 can instruct the magnetic memory device 1 to perform a read operation, a write operation, etc. in response to a request (or command) from an external host device.

### 1.1. Configuration of Magnetic Memory Device

Next, the configuration of the magnetic memory device 1 of the first embodiment will be described with reference to FIG. 1.

The magnetic memory device 1 is one type of resistance change memory. The magnetic memory device 1 is a memory device that uses magnetic tunnel junction (MTJ) elements as memory cells. The MTJ elements utilize the magnetoresistance effect caused by a magnetic tunnel junction. The MTJ elements are referred to as magnetoresistance effect elements as well.

The magnetic memory device 1 includes, for example, a memory cell array 11, an input/output circuit 12, a control circuit 13, a row selection circuit 14, a column selection circuit 15, a write circuit 16, and a read circuit 17.

The memory cell array 11 includes a plurality of memory cells MC, a plurality of word lines WL, and a plurality of bit lines BL. FIG. 1 shows one set of a memory cell MC, a word line WL, and a bit line BL. The memory cells MC can store data in a nonvolatile manner. Each memory cell MC is coupled between one word line WL and one bit line BL, and is associated with a pair of a row and a column. A row address is assigned to the word line WL. A column address is assigned to the bit line BL. One or more memory cells MC can be specified by selecting one row and one or more columns.

The input/output circuit 12 is coupled to the memory controller 2 and manages communication between the magnetic memory device 1 and the memory controller 2. The input/output circuit 12 transfers a control signal CNT and a command CMD, received from the memory controller 2, to the control circuit 13. Also, the input/output circuit 12 transfers a row address and a column address, included in an address signal ADD received from the memory controller 2, to the row selection circuit 14 and the column selection circuit 15, respectively. The input/output circuit 12 transfers data DAT (write data), received from the memory controller 2, to the write circuit 16. The input/output circuit 12 transfers data DAT (read data), received from the read circuit 17, to the memory controller 2.

The control circuit 13 controls the overall operation of the magnetic memory device 1. For example, the control circuit 13 executes a read operation, a write operation, etc., based on the control indicated by the control signal CNT and the command CMD. For example, in a write operation, the control circuit 13 supplies the write circuit 16 with a voltage and a control signal used for data write. In a read operation, the control circuit 13 supplies the read circuit 17 with a voltage and a control signal used for data read.

The row selection circuit 14 is coupled to the plurality of word lines WL. The row selection circuit 14 selects one word line WL specified by a row address. The selected word line WL is electrically coupled, for example, to a driver circuit (not shown).

The column selection circuit 15 is coupled to the plurality of bit lines BL. The column selection circuit 15 selects one or more bit lines BL specified by a column address. The selected bit lines BL are electrically coupled, for example, to a driver circuit (not shown).

The write circuit 16 supplies a voltage used for data write to the column selection circuit 15, based on the control of the control circuit 13 and the data DAT (write data) received from the input/output circuit 12. In a case where a current based on the write data flows through the memory cell MC, desired data is written to the memory cell MC.

The read circuit 17 includes a sense amplifier. The read circuit 17 supplies a voltage used for data read to both the row selection circuit 14 and the column selection circuit 15, under the control of the control circuit 13. The sense amplifier determines the data stored in the memory cell MC, based on the voltage or current of the selected memory cell MC and word line WL. Furthermore, the read circuit 17 transfers data DAT (read data) corresponding to the determination result to the input/output circuit 12. Details of the read circuit 17 will be described later.

### 1.1.1 Circuit Configuration of Memory Cell Array

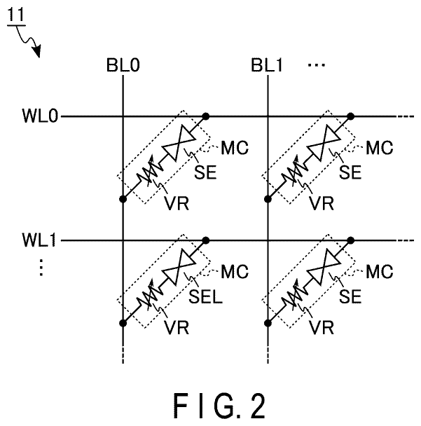

An example of a circuit configuration of the memory cell array 11 provided in the magnetic memory device 1 of the first embodiment will be described with reference to FIG. 2. FIG. 2 is a circuit diagram showing the configuration of the memory cell array 11 provided in the magnetic memory device 1. FIG. 2 shows WL0 and WL1 of the plurality of word lines WL, and BL0 and BL1 of the plurality of bit lines BL.

As shown in FIG. 2, one memory cell MC is coupled between WL0 and BL0, between WL0 and BL1, between WL1 and BL0, and between WL1 and BL1. The plurality of memory cells MC are arranged, for example, in a matrix pattern in the memory cell array 11.

Each memory cell MC includes a variable resistance element VR and a selector element SE. The variable resistance element VR and the selector element SE are coupled in series between the associated bit line BL and word line WL. For example, one end of the variable resistance element VR is coupled to the bit line BL. The other end of the variable resistance element VR is coupled to one end of the selector element SE. The other end of the selector element SE is coupled to the word line WL. The coupling relationship between the variable resistance element VR and the selector element SE may be reversed between the bit line BL and the word line WL. In this case, one end of the variable resistance element VR is coupled to the word line WL, and the other end of the variable resistance element VR is coupled to one end of the selector element SE. The other end of the selector element SE is coupled to the bit line BL.

The variable resistance element VR corresponds to an MTJ element (i.e., a magnetoresistance effect element). The variable resistance element VR can store data in a nonvolatile manner, based on the resistance value thereof. For example, a memory cell MC including a variable resistance element VR in a high resistance state stores “1” data. A memory cell MC including a variable resistance element VR in a low resistance state stores “0” data. The assignment of data associated with the resistance value of the variable resistance element VR may be set in a different way. The resistance state of the variable resistance element VR can change in accordance with the current flowing through the variable resistance element VR.

The selector element SE is, for example, a bidirectional diode having a snapback characteristic. The selector element SE functions as a selector that controls the supply of a current to the associated variable resistance element VR.

Specifically, the selector element SE included in a certain memory cell MC is turned off (or becomes decoupled) in a case where the voltage applied to the memory cell MC is lower than the threshold voltage of the selector element SE, and is turned on (or becomes coupled) in a case where the voltage applied to the memory cell MC is higher than or equal to the threshold voltage of the selector element SE. The selector element SE in the off state functions as an insulator having a high resistance value. In a case where the selector element SE is in the off state, the flow of current is suppressed between the word line WL and bit line BL coupled to the memory cell MC. The selector element SE in the on state functions as a conductor having a low resistance value. In a case where the selector element SE is in the on state, a current flows between the word line WL and bit line BL coupled to the memory cell MC. In other words, the selector element SE can switch whether or not to permit the flow of a current in accordance with the magnitude of the voltage applied to the memory cell MC, regardless of the direction in which the current flows. The snapback characteristic of the selector element SE will be described later. It should be noted that the selector element SE may be replaced with another element such as a transistor.

### 1.1.2 Structure of Memory Cell Array

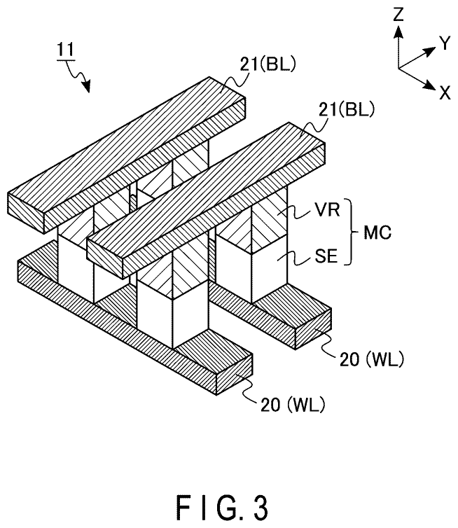

An example of the structure of the memory cell array 11 provided in the magnetic memory device 1 of the first embodiment will be described with reference to FIG. 3. FIG. 3 is a perspective view showing the structure of the memory cell array 11 provided in the magnetic memory device 1. In the description below, an XYZ orthogonal coordinate system is used. The X direction corresponds to the direction in which the word lines WL extend. The Y direction corresponds to the direction in which the bit lines BL extend. The Z direction corresponds to the direction perpendicular to the surface of the semiconductor substrate used to form the magnetic memory device 1. The description “below” and its derivatives and related words indicate a position of a smaller coordinate on the Z axis. The description “above” and its derivatives and related words indicate a position of a larger coordinate on the Z axis. Hatching is added to the perspective view where appropriate. The hatching added to the perspective view is not necessarily related to the materials or characteristics of the hatched components. In the perspective views and cross-sectional views, illustration of configurations such as interlayer insulating films is omitted.

As shown in FIG. 3, the memory cell array 11 includes a plurality of conductive layers 20, a plurality of conductive layers 21, and a plurality of memory cells MC.

Each of the plurality of conductive layers 20 has a portion extending in the X direction. The plurality of conductive layers 20 are arranged side by side in the Y direction and are spaced apart from each other. Each conductive layer 20 is used as a word line WL.

Each of the plurality of conductive layers 21 has a portion extending in the Y direction. The plurality of conductive layers 21 are arranged side by side in the X direction and are spaced apart from each other. Each conductive layer 21 is used as a bit line BL.

An interconnect layer including the plurality of conductive layers 21 is provided above the interconnect layer including the plurality of conductive layers 20. One memory cell MC is provided at each of the intersections between the plurality of conductive layers 20 and the plurality of conductive layers 21. In other words, each memory cell MC is provided between the associated word line WL and bit line BL. Each memory cell MC has a columnar structure. In this example, a selector element SE is provided on the conductive layer 20. A variable resistance element VR is provided on the selector element SE. A conductive layer 21 is provided on the variable resistance element VR.

Although the example has been given of the case where the variable resistance element VR is provided above the selector element SE, this is not restrictive. Depending on the circuit configuration of the memory cell array 11, the variable resistance element VR may be provided below the selector element SE. Furthermore, other elements or conductive layers may be inserted between the memory cell MC and the conductive layer 20. Similarly, other elements or conductive layers may be inserted between the memory cell MC and the conductive layer 21. Each of the conductive layers 20 and 21 may be referred to as an “interconnect.”

### 1.1.3 Cross-Sectional Structure of Memory Cell

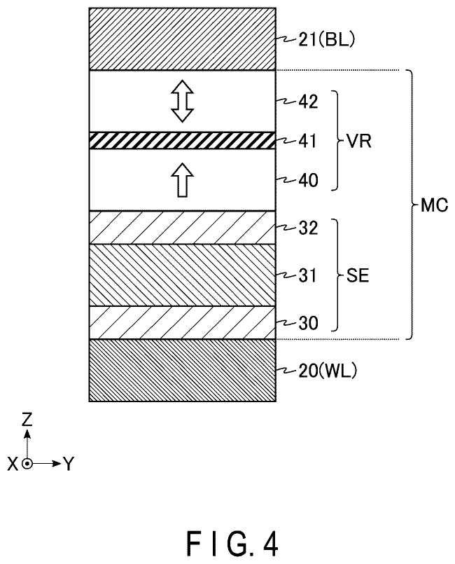

An example of the memory cell MC included in the memory cell array 11 of the magnetic memory device 1 of the first embodiment will be described with reference to FIG. 4. FIG. 4 is a cross-sectional view of the memory cell MC included in the memory cell array 11.

As shown in FIG. 4, the memory cell MC has a structure in which a lower electrode 30, a selector material layer 31, an upper electrode 32, a ferromagnetic layer 40, a nonmagnetic layer 41, and a ferromagnetic layer 42 are stacked on the conductive layer 20 upward (in the Z direction) in this order.

That is, the lower electrode 30 is provided above the conductive layer 20 (in the Z direction). The selector material layer 31 is provided above the lower electrode 30. The upper electrode 32 is provided above the selector material layer 31. The ferromagnetic layer 40 is provided above the upper electrode 32. The nonmagnetic layer 41 is provided above the ferromagnetic layer 40. The ferromagnetic layer 42 is provided above the nonmagnetic layer 41. The conductive layer 21 is provided above the ferromagnetic layer 42.

In other words, the nonmagnetic layer 41 is provided between the ferromagnetic layer 40 and the ferromagnetic layer 42. The ferromagnetic layer 40 is provided between the nonmagnetic layer 41 and the upper electrode 32. The upper electrode 32 is provided between the ferromagnetic layer 40 and the selector material layer 31. The selector material layer 31 is provided between the upper electrode 32 and the lower electrode 30. The lower electrode 30 is provided between the selector material layer 31 and the conductive layer 20. Furthermore, the ferromagnetic layer 42 is provided between the nonmagnetic layer 41 and the conductive layer 21.

The set of the lower electrode 30, the selector material layer 31, and the upper electrode 32 corresponds to the selector element SE. The set of the ferromagnetic layer 40, the nonmagnetic layer 41 and the ferromagnetic layer 42 corresponds to the variable resistance element VR.

Each of the ferromagnetic layers 40 and 42 is made of a ferromagnetic material and has a magnetization direction perpendicular to the film surface. For example, in the magnetic memory device 1, the magnetization direction of the ferromagnetic layer 40 is fixed, and the magnetization direction of the ferromagnetic layer 42 is variable. In this case, the ferromagnetic layer 40 functions as a reference layer of the MTJ element, and the ferromagnetic layer 42 functions as a storage layer of the MTJ element. The nonmagnetic layer 41 is made of an insulator such as MgO and functions as a tunnel barrier layer. The ferromagnetic layers 40 and 42 form a magnetic tunnel junction together with the nonmagnetic layer 41. Such a variable resistance element VR functions as a perpendicular magnetization type MTJ element utilizing the TMR (tunneling magnetoresistive) effect.

The ferromagnetic layer 40 contains at least one element selected from the group consisting of iron (Fe), cobalt (Co) and nickel (Ni). The nonmagnetic layer 41 contains an oxide of at least one element or compound selected from the group consisting of magnesium (Mg), aluminum (Al), zinc (Zn), titanium (Ti), and LSM (lanthanum-strontium-manganese). The ferromagnetic layer 42 contains at least one element selected from the group consisting of iron (Fe), cobalt (Co) and nickel (Ni).

The variable resistance element VR can be in either a low resistance state or a high resistance state in accordance with the relative relationship between the magnetization directions of the ferromagnetic layers 40 and 42. The variable resistance element VR stores data in accordance with the magnetization direction of the ferromagnetic layer 42 (storage layer). For example, the variable resistance element VR in which the magnetization directions of the reference layer and the storage layer are antiparallel (AP state) is in a high resistance state (“1” data). On the other hand, the variable resistance element VR in which the magnetization directions of the reference layer and the storage layer are parallel (P state) is in a low resistance state (“0” data).

In this example, the variable resistance element VR is in the AP state in a case where a write current flows from the ferromagnetic layer 40 to the ferromagnetic layer 42, and is in the P state in a case where the write current flows from the ferromagnetic layer 42 to the ferromagnetic layer 40. A write method in which a spin torque is injected into the storage layer and the reference layer by causing a write current to flow through the variable resistance element VR in the above manner and the magnetization direction of the storage layer is controlled thereby is referred to as a spin transfer torque writing method. The variable resistance element VR is configured such that the magnetization direction of the ferromagnetic layer 40 does not change when a current of a magnitude capable of reversing the magnetization direction of the ferromagnetic layer 42 is made to flow through the variable resistance element VR.

In the present specification, the phrase “magnetization direction is variable” is intended to mean that the magnetization direction changes in response to the write current. The phrase “magnetization direction is fixed” is intended to refer to the state where the magnetization direction does not vary due to the write current. In the variable resistance element VR, the arrangement of the storage layer and the reference layer may be interchanged. The variable resistance element VR may also include other layers. For example, the variable resistance element VR may include a shift cancellation layer that suppresses the influence of a leakage magnetic field from the reference layer, or have a synthetic anti-ferromagnetic (SAF) structure, etc. In the description below, a memory cell MC including a variable resistance element VR in the AP state will be referred to as a memory cell MC in the AP state, and a memory cell MC including a variable resistance element VR in the P state will be referred to as a memory cell MC in the P state.

### 1.1.4 Circuit Configuration of Read Circuit

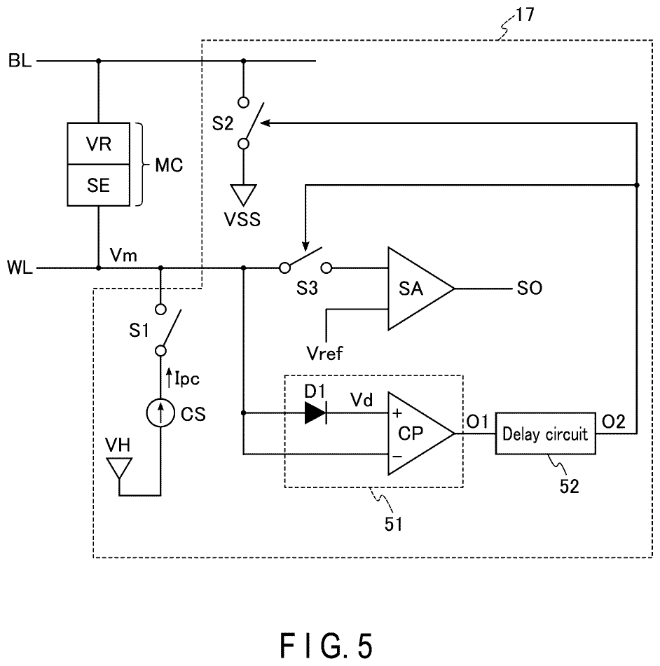

An example of a circuit configuration of the read circuit 17 included in the magnetic memory device 1 of the first embodiment will be described with reference to FIG. 5. FIG. 5 is a circuit diagram showing the configuration of the read circuit 17 included in the magnetic memory device 1. FIG. 5 shows the read circuit 17, a pair of bit line BL and word line WL included in the memory cell array 11, and a memory cell MC.

As shown in FIG. 5, the read circuit 17 includes a constant current source CS, a power supply VH, a peak detection circuit 51, a delay circuit 52, a sense amplifier SA, a precharge switch S1, a sink switch S2, and a sense amplifier switch S3. The peak detection circuit 51 includes a comparator CP and a diode D1.

The constant current source CS is coupled to the word line WL via the precharge switch S1. The power supply VH is coupled to the constant current source CS.

The word line WL is coupled to a first input terminal of the sense amplifier SA via the sense amplifier switch S3. A reference voltage Vref is supplied to a second input terminal of the sense amplifier SA. The sense amplifier SA compares the voltage Vm of the memory cell MC (or the selector element SE) and the word line WL, which is input to the first input terminal, with the reference voltage Vref, and outputs a signal SO based on the comparison result.

The word line WL is coupled to a positive input terminal (or a non-inverting input terminal) of the comparator CP via the diode D1. Furthermore, the word line WL is coupled to a negative input terminal (or the inverting input terminal) of the comparator CP.

An output terminal of the comparator CP is coupled to an input terminal of the delay circuit 52. An output terminal of the delay circuit 52 is coupled to a control terminal of the sink switch S2 and a control terminal of the sense amplifier switch S3. The control terminal of the sink switch S2 is a terminal for controlling the sink switch S2 to either a coupled state (a closed state or an on state) or a decoupled state (an open state or an off state). The control terminal of the sense amplifier switch S3 is a terminal for controlling the sense amplifier switch S3 to either the coupled state or the decoupled state.

The bit line BL is coupled to a ground voltage VSS node via the sink switch S2. The ground voltage VSS is supplied to the ground voltage VSS node.

The memory cell MC is coupled between the word line WL and the bit line BL. The memory cell MC includes a selector element SE and a variable resistance element VR coupled in series. That is, one end of the selector element SE is coupled to the word line WL, and one end of the variable resistance element VR is coupled to the other end of the selector element SE. Furthermore, the bit line BL is coupled to the other end of the variable resistance element VR.

The constant current source CS supplies a precharge current Ipc to the memory cell MC (or the selector element SE) and the word line WL via the precharge switch S1, thereby charging the memory cell MC (or the selector element SE) and the word line WL. The precharge current Ipc is a constant current, and the voltage Vm of the memory cell MC (or the selector element SE) and the word line WL gradually increases in accordance with the supply of the precharge current Ipc. The voltage Vm of the memory cell MC (or the selector element SE) and the word line WL is a voltage between the terminals coupled to the word line WL and the bit line BL of the memory cell MC, that is, a voltage between the word line WL and the bit line BL that sandwich the memory cell MC. In the description below, the voltage Vm of the memory cell MC (or the selector element SE) and the word line WL will be referred to as the voltage Vm of the memory cell MC and the word line WL, or as the voltage Vm of the memory cell MC.

The peak detection circuit 51 detects a peak voltage of the voltage Vm of the memory cell MC when the precharge current Ipc is supplied to the memory cell MC. The peak voltage of the voltage Vm of the memory cell MC corresponds to the threshold voltage Vth of the selector element SE of the memory cell MC.

The memory cell MC is charged by the precharge current Ipc supplied from the constant current source CS, and the voltage Vm of the memory cell MC rises and reaches the threshold voltage Vth. Then, the selector element SE transitions to the on state (or the coupled state). Thus, a cell current Im begins to flow from the memory cell MC to the ground voltage VSS node via the sink switch S2. Thereafter, the voltage Vm of the memory cell MC drops due to the snapback characteristic of the selector element SE, and is further decreased due to the cell current Im. Therefore, the threshold voltage Vth is the peak voltage of the voltage Vm of the memory cell MC.

As described above, the peak detection circuit 51 includes the comparator CP and the diode D1. The voltage Vm of the memory cell MC is input to the positive input terminal of the comparator CP via the diode D1. Let it be assumed that the voltage between the cathode of the diode D1 and the positive input terminal of the comparator CP is a voltage Vd. The voltage Vm of the memory cell MC is input directly to the negative input terminal of the comparator CP without passing through a diode.

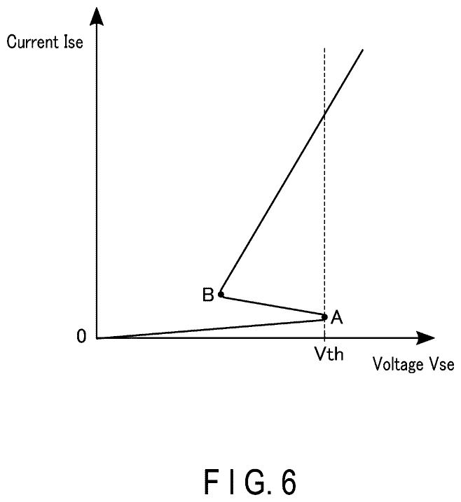

The snapback characteristic of the selector element SE of the memory cell MC will be described below with reference to FIG. 6. FIG. 6 is a graph showing the current-voltage characteristics of the snapback characteristic of the selector element SE. The horizontal axis represents a voltage Vse applied to the selector element SE. The vertical axis represents a current Ise flowing through the selector element SE.

When the voltage Vse applied to the selector element SE rises from 0, a small current flows through the selector element SE and gradually rises. The selector element SE is in the off state until the voltage Vse reaches the threshold voltage Vth of the selector element SE.

When the voltage Vse further rises and reaches the threshold voltage Vth at point A, the selector element SE transitions to the on state. Thus, the voltage Vse drops sharply to point B, and then rises again. The current Ise increases sharply from point B.

The phenomenon in which the voltage Vse applied to the selector element SE drops sharply when it reaches the threshold voltage Vth of the selector element SE is referred to as a snapback characteristic. In the present embodiment, this snapback characteristic is used to detect that the voltage Vm of the memory cell MC has reached the threshold voltage Vth, since the voltage Vm drops below the diode voltage Vd immediately after the voltage Vm of the memory cell MC reaches the threshold voltage Vth.

The comparator CP of the peak detection circuit 51 compares the voltage Vm of the memory cell MC with the voltage Vd, and determines, based on the comparison result, whether the voltage Vm of the memory cell MC has reached the peak voltage, i.e., whether the voltage Vm of the memory cell MC has reached the threshold voltage Vth of the selector element SE. The comparator CP outputs a signal O1 based on the determination result.

When the voltage Vm of the memory cell MC reaches the threshold voltage Vth, the selector element SE transitions to the on state. This starts discharging the voltage Vm of the memory cell MC, i.e., the charge in the memory cell MC is discharged. That is, the cell current Im starts flowing from the memory cell MC to the ground voltage VSS node via the sink switch S2.

For example, in a case where the voltage Vd of the diode D1 is lower than the voltage Vm of the memory cell MC, the comparator CP outputs, for example, a low-level voltage (hereinafter, referred to as “L”) as a signal O1 indicating that the voltage Vm of the memory cell MC has not reached the threshold voltage Vth. On the other hand, in a case where the voltage Vm of the memory cell MC reaches the threshold voltage Vth and then drops due to the snapback characteristic of the selector element SE, causing the voltage Vd to exceed the voltage Vm, the comparator CP outputs a high-level voltage (hereinafter referred to as “H”) higher than “L,” as a signal O1 indicating that the voltage Vm of the memory cell MC has reached the threshold voltage Vth. It should be noted that the peak detection circuit 51 is provided, for example, for each word line WL.

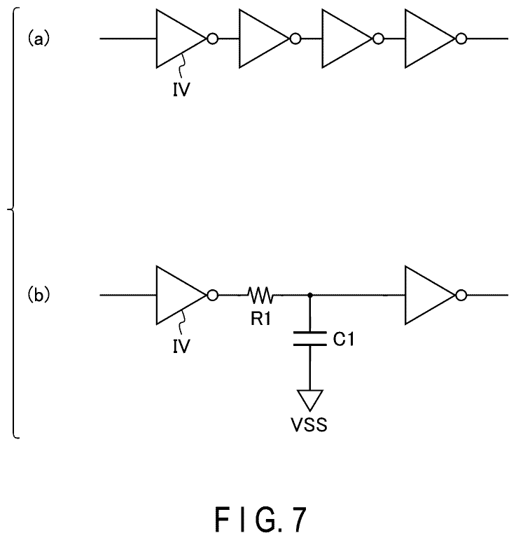

The delay circuit 52 delays the signal O1 output from the comparator CP by a predetermined delay time and outputs a signal O2. FIG. 7 is a diagram showing an example of the configuration of the delay circuit 52. For example, as shown in (a) of FIG. 7, the delay circuit 52 has a configuration in which an even number of inverters IV are coupled in series. Alternatively, as shown in (b) of FIG. 7, the delay circuit 52 has a configuration including two inverters IV, and a resistive element R1 and a capacitive element C1 coupled between the inverters IV.

The delay time provided by the delay circuit 52 is set to be shorter than the time from when the voltage Vm of the memory cell MC reaches the threshold voltage Vth, that is, from when the cell current Im begins to flow, until the voltage Vm of the memory cell MC drops to a hold voltage Vh. The hold voltage Vh is a voltage retained by the memory cell MC after the cell has been charged to the threshold voltage Vth, the cell current Im flows through the memory cell MC, and the cell current Im (or the discharge current) ceases to flow.

The sense amplifier SA is configured to compare the voltage Vm of the memory cell MC with the reference voltage Vref when data stored in the memory cell MC is read, and to determine the data stored in the memory cell MC, based on the comparison result.

The reference voltage Vref is a voltage that is used as a threshold in determining whether data is “0” or “1.” For example, in a case where the voltage Vm of the memory cell MC is equal to or higher than Vref, the sense amplifier SA outputs a voltage corresponding to “1” data as a signal SO. On the other hand, in a case where the voltage Vm of the memory cell MC is lower than Vref, the sense amplifier SA outputs a voltage corresponding to “0” data as a signal SO. It should be noted that a sense amplifier SA is provided, for example, for each word line WL.

The precharge switch S1 is a switch that switches, under the control of the control circuit 13, between the supply of the precharge current Ipc to the memory cell MC and the stopping of the supply of the precharge current Ipc. The precharge switch S1 is coupled between the word line WL (or the memory cell MC) and the constant current source CS. Under the control of the control circuit 13, the precharge switch S1 sets the state between the word line WL and the constant current source CS to either the coupled state (the closed state or the on state) or the decoupled state (the open state or the off state).

For example, when the precharge switch S1 is set to the coupled state, the precharge current Ipc is supplied from the constant current source CS to the memory cell MC and the word line WL. On the other hand, when the precharge switch S1 is set to the decoupled state, the supply of the precharge current Ipc from the constant current source CS to the memory cell MC and the word line WL is stopped. The precharge switch S1 includes, for example, an n-type MOS field effect transistor.

The sink switch S2 controls a cell current Im flowing from the memory cell MC to the ground voltage VSS node, based on the signal O2 output from the delay circuit 52. That is, the sink switch S2 is a switch that switches between the discharging of the charge from the memory cell MC and the stopping of the discharge. The sink switch S2 is coupled between the bit line BL (or the memory cell MC) and the ground voltage VSS node. The sink switch S2 sets the bit line BL and the ground voltage VSS node to either the coupled state or the decoupled state, based on the output signal O2 from the delay circuit 52. For example, when the sink switch S2 is set to the coupled state, the cell current Im flows from the memory cell MC to the ground voltage VSS node, and the charge in the memory cell MC is discharged. On the other hand, when the sink switch S2 is set to the decoupled state, no cell current Im flows from the memory cell MC to the ground voltage VSS node, and the discharging of the memory cell MC is stopped. The sink switch S2 includes, for example, an n-type MOS field effect transistor.

The sense amplifier switch S3 is set to the decoupled state when data is read from the memory cell MC, based on the signal O2 output from the delay circuit 52. On the other hand, when data is not read from the memory cell MC, the sense amplifier switch S3 is set to the coupled state. The sense amplifier switch S3 is coupled between the word line WL (or memory cell MC) and the sense amplifier SA. The sense amplifier switch S3 sets the word line WL and the sense amplifier SA to either the coupled state or the decoupled state, based on the signal O2 output from the delay circuit 52. The sense amplifier switch S3 includes, for example, an n-type MOS field effect transistor.

The relationship between inputs to the positive and negative input terminals of the comparator CP and outputs from the comparator CP, the number of inverters included in the delay circuit 52, and the polarity of the voltage at which the precharge switch S1, the sink switch S2 and the sense amplifier switch S3 are set to either the coupled state or the decoupled state can be set arbitrarily as long as the configuration enables the operation. For example, if the relationship between inputs to the positive and negative input terminals of the comparator CP and outputs from the comparator CP is reversed, the number of inverters of the delay circuit 52 is set to be an odd number.

### 1.2 Read Operation of Magnetic Memory Device

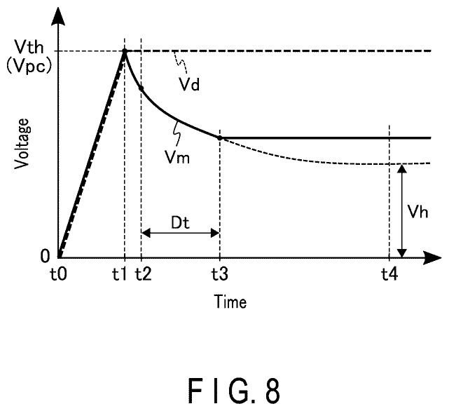

The read operation of the magnetic memory device 1 of the first embodiment will be described with reference to FIG. 8. FIG. 8 is a graph showing voltage changes in the voltage Vm of the memory cell MC and the voltage Vd of the diode D1 in the read operation of the magnetic memory device 1. In FIG. 8, the horizontal axis represents time and the vertical axis represents a voltage.

The voltage Vm of the memory cell MC is a voltage charged (or held) in the memory cell MC (or the selector element SE) and the word line WL. In other words, the voltage Vm of the memory cell MC is a voltage obtained by subtracting the voltage of the bit line BL from the voltage of the word line WL. The read operation is controlled by the control circuit 13 and the read circuit 17.

First, the precharge current Ipc is supplied to the memory cell MC from the constant current source CS. This causes the voltage Vm of the memory cell MC to rise. When the voltage Vm of the memory cell MC rises to the threshold voltage Vth of the selector element SE at time t1, the selector element SE is turned on and the cell current Im starts to flow through the memory cell MC.

When the selector element SE is turned on, the snapback characteristic of the selector element SE causes the voltage Vm, which has risen to the threshold voltage Vth, to suddenly drop. On the other hand, the voltage Vd of the diode D1 maintains the peak voltage (i.e., the threshold voltage Vth) reached before the voltage Vm drops, owing to the backflow prevention function of the diode.

At time t2, the peak detection circuit 51 detects that the voltage Vm of the memory cell MC has dropped below the voltage Vd of the diode D1, that is, the voltage Vm of the memory cell MC has reached the threshold voltage Vth of the selector element SE. In response to the detection that the voltage Vm has reached the threshold voltage Vth, the control circuit 13 sets the precharge switch S1 to the decoupled state. This stops the supply of the precharge current Ipc, preventing excess precharge current Ipc from being supplied to the memory cell MC.

Then, the control circuit 13 reads the memory cell MC at time t3 after a predetermined delay time Dt has elapsed from the detection that the voltage Vm has reached the threshold voltage Vth.

The supply of the precharge current Ipc, the detection of the voltage Vm of the memory cell MC reaching the threshold voltage Vth, the stopping of the supply of the precharge current Ipc, and the reading of the memory cell MC are performed individually for each memory cell.

The voltage of the memory cell MC at time t4 shown in FIG. 8 is the hold voltage Vh described above. The hold voltage Vh is defined as a voltage at which the sink switch S2 remains in the coupled state until the cell current Im, i.e., the discharge current, ceases to flow. This occurs after the voltage Vm of the memory cell MC reaches the threshold voltage Vth and the cell current Im begins to flow. The control circuit 13 may wait until the voltage Vm of the memory cell MC reaches the hold voltage Vh, and then read the memory cell MC having the hold voltage Vh.

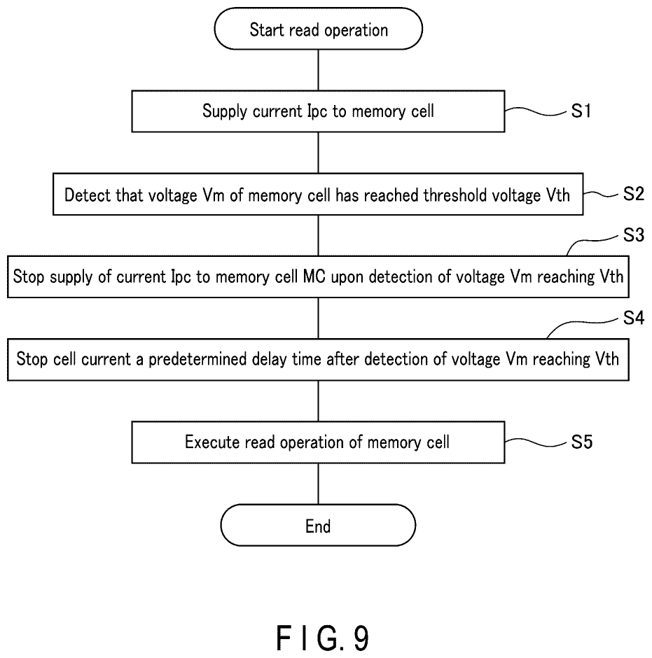

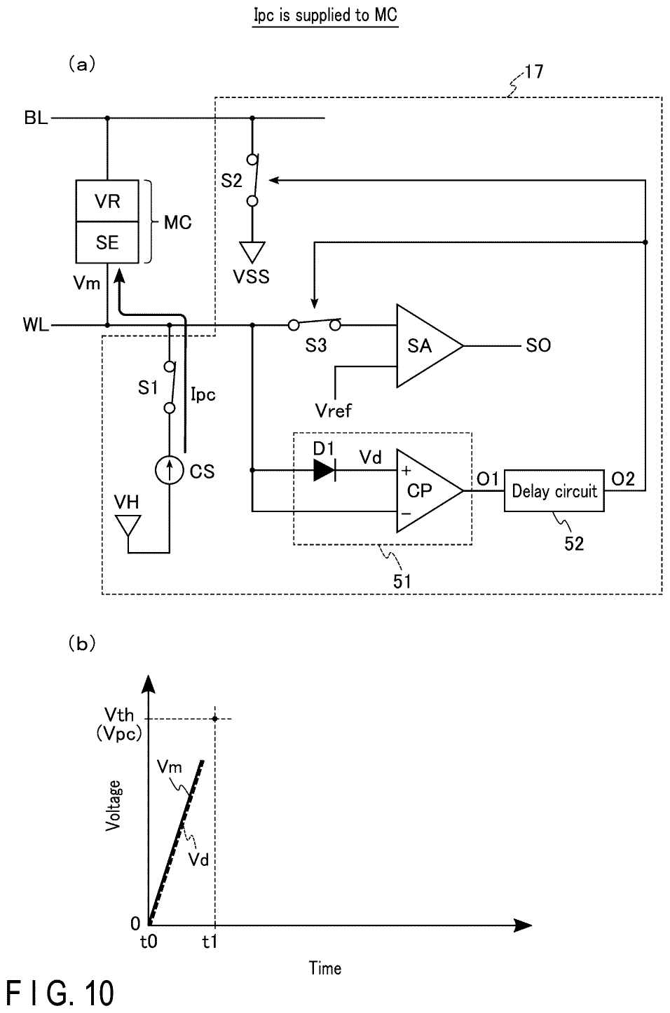

The read operation of the magnetic memory device 1 of the first embodiment will be described in detail below with reference to FIG. 9 to FIG. 13. FIG. 9 is a flowchart illustrating the flow of the read operation of the magnetic memory device 1. FIGS. 10 to 13 are diagrams showing the states of the switches, the current flow, and the voltage changes in the voltages Vm and Vd in a read operation.

First, the read circuit 17 causes the constant current source CS to supply the precharge current Ipc to the memory cell MC (S1).

Specifically, as shown in (a) of FIG. 10, at time to, the read circuit 17 sets the precharge switch S1, the sink switch S2, and the sense amplifier switch S3 to the coupled state. Thus, the precharge current Ipc is supplied from the constant current source CS to the memory cell MC, and the memory cell MC (or the selector element SE) and the word line WL are charged. As shown in (b) of FIG. 10, the voltage Vm of the memory cell MC and the voltage Vd of the diode D1 rise in a similar manner. It should be noted that at this point in time, the voltage Vm of the memory cell MC has not yet reached the threshold voltage Vth of the selector element SE.

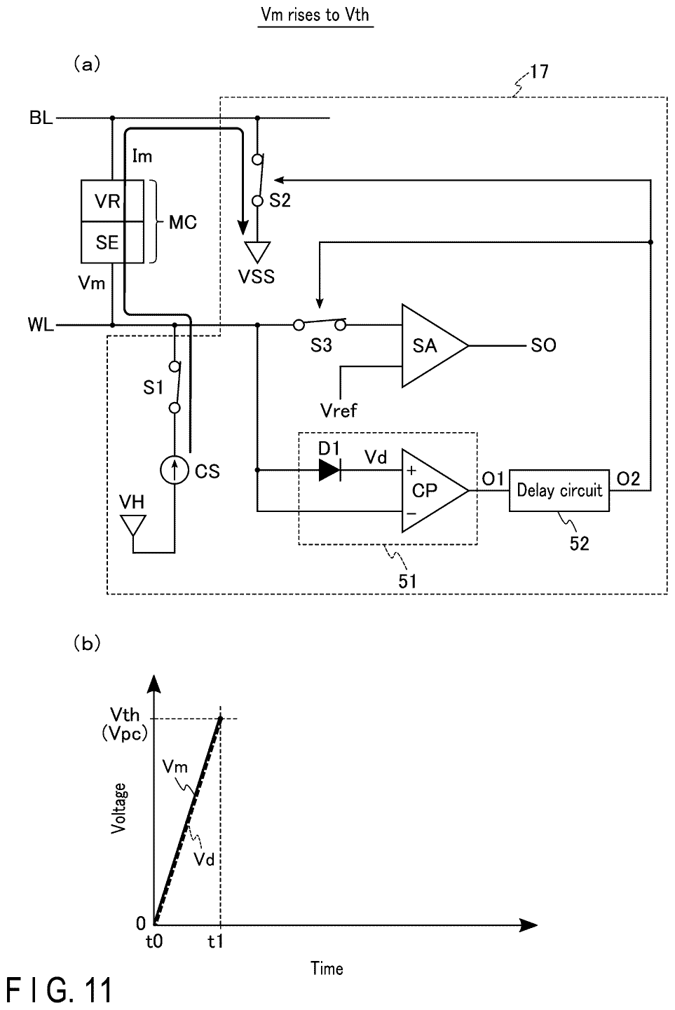

Next, the voltage Vm of the memory cell MC rises due to the supply of the precharge current Ipc, and as shown in (b) of FIG. 11, the voltage Vm of the memory cell MC reaches the threshold voltage Vth of the selector element SE at time t1. When the voltage Vm of the memory cell MC reaches the threshold voltage Vth, the selector element SE transitions to the on state, and as shown in (a) of FIG. 11, the cell current Im begins to flow through the memory cell MC.

Next, the peak detection circuit 51 detects that the voltage Vm of the memory cell MC has reached the threshold voltage Vth of the selector element SE (S2).

Specifically, the voltage Vm of the memory cell MC is input to the positive input terminal of the comparator CP via the diode D1. That is, the voltage Vm of the memory cell MC is input to the anode of the diode D1, and the voltage Vd output from the cathode of the diode D1 is input to the positive input terminal of the comparator CP. Meanwhile, the voltage Vm of the memory cell MC is input to the negative input terminal of the comparator CP.

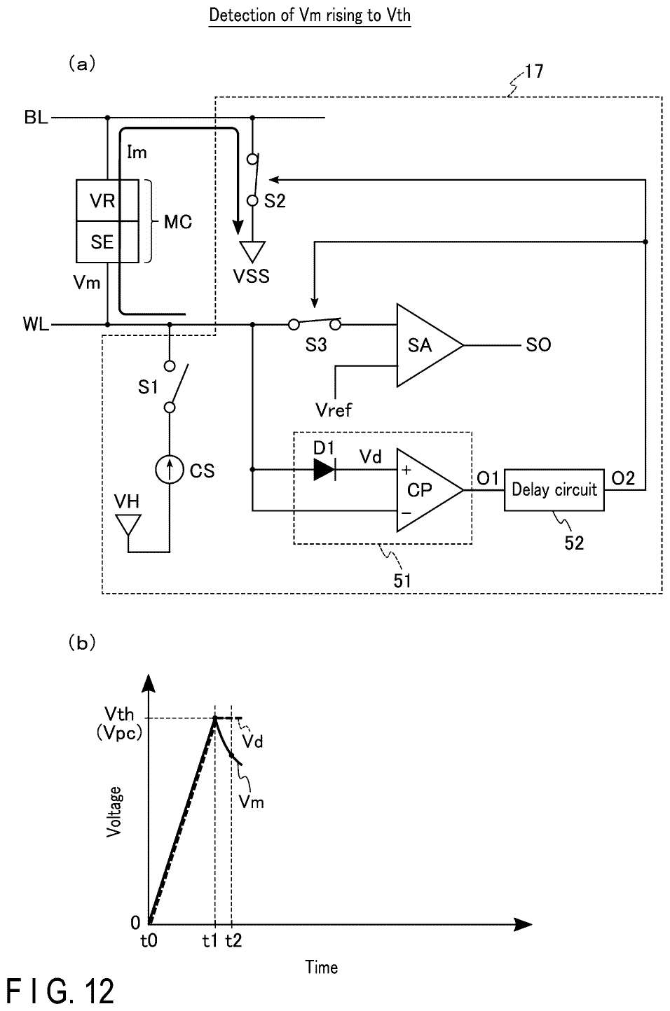

When the voltage Vm of the memory cell MC reaches the threshold voltage Vth of the selector element SE, the selector element SE transitions to the on state. As shown in (b) of FIG. 12, after time t1, the voltage Vm drops suddenly due to the snapback characteristic of the selector element SE. Meanwhile, the voltage Vd on the cathode side of the diode D1 (or the voltage at the positive input terminal of the comparator CP) is maintained at the threshold voltage Vth, owing to the backflow prevention function of the diode D1.

At time t2, the comparator CP compares the voltage Vd input to the positive input terminal with the voltage Vm input to the negative input terminal. Since the voltage Vd is higher than the voltage Vm, the comparator CP outputs “H” as the signal O1. The “H” of the signal O1 is a signal indicating that the voltage Vm of the memory cell MC has reached the threshold voltage Vth.

Next, when the peak detection circuit 51 detects that the voltage Vm of the memory cell MC has reached the threshold voltage Vth, the read circuit 17 stops the supply of the precharge current Ipc to the memory cell MC in response to a command from the control circuit 13 issued in accordance with that detection (S3).

Specifically, the signal O1 output from the comparator CP of the peak detection circuit 51 is sent to the control circuit 13. When the control circuit 13 receives the signal O1 at “H,” it sends a signal to the read circuit 17, transitioning the precharge switch S1 to the decoupled state. The read circuit 17 sets the precharge switch S1 to the decoupled state in response to the signal from the control circuit 13, as shown in (a) of FIG. 12. The sink switch S2 and the sense amplifier switch S3 are maintained in the coupled state.

This stops the supply of the precharge current Ipc from the constant current source CS to the memory cell MC. However, the cell current Im continues to flow from the memory cell MC and the word line WL to the ground voltage node via the sink switch S2. The voltage Vm of the memory cell MC drops below the threshold voltage Vth due to the snapback characteristic, and drops further due to the cell current Im.

Next, the read circuit 17 detects that a predetermined delay time Dt has elapsed since the voltage Vm of the memory cell MC has reached the threshold voltage Vth and, in response to this detection, stops the cell current Im flowing from the memory cell MC and the word line WL (S4).

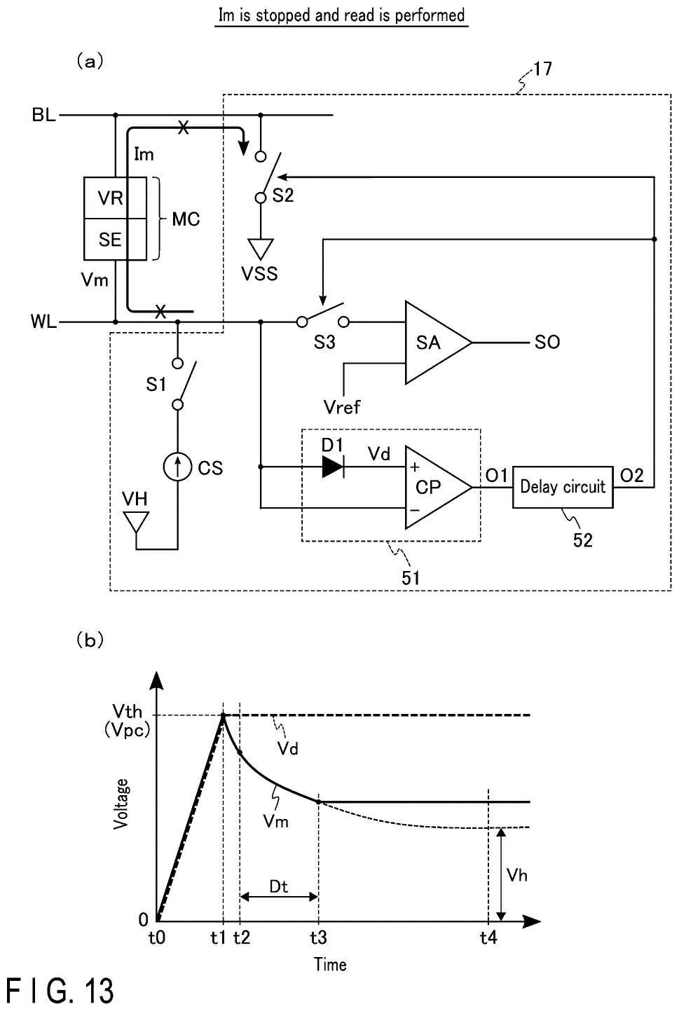

Specifically, the signal O1 output from the comparator CP is input to the delay circuit 52. The delay circuit 52 delays the received signal O1 by a predetermined delay time Dt, and outputs the signal O2 to the control terminals of the sink switch S2 and the sense amplifier switch S3. As shown in (a) of FIG. 13, when the sink switch S2 receives “H” as the signal O2, it transitions from the coupled state to the decoupled state. Similarly, when the sense amplifier switch S3 receives “H” as the signal O2, it transitions from the coupled state to the decoupled state. Thus, as shown in (a) and (b) of FIG. 13, at time t3, the cell current Im flowing from the memory cell MC and word line WL is stopped. The voltage Vm of the memory cell MC at this time is held in the sense amplifier SA.

Then, the read circuit 17 performs a read operation for the memory cell MC (S5).

Specifically, the sense amplifier SA compares the voltage Vm of the memory cell MC held at time t3 with the reference voltage Vref, and determines the data stored in the memory cell MC, based on the comparison result.

### 1.3 Advantages of First Embodiment

The magnetic memory device 1 of the first embodiment is advantageous in that discharge failures and read disturb failures in a read operation can be reduced and the operating performance can be improved. The advantages of the embodiment will be described below.

For example, in the read operation of the memory cell in the magnetic memory device, the memory cell is charged to the precharge voltage Vpc and then the precharge voltage Vpc charged to the memory cell is discharged. Then, a resistance value of the variable resistance element is read from the voltage of the memory cell after discharge or the voltage of the memory cell during discharge. Data is determined from the read resistance value.

For this reason, the precharge voltage Vpc charged to each memory cell must be equal to or greater than the threshold voltage Vth of the selector element of the memory cell. Otherwise, a discharge failure occurs in which the precharge voltage Vpc charged to the memory cell does not discharge.

However, the threshold voltage Vth of the selector element in the memory cell varies for each selector element. For this reason, in order to set the precharge voltage Vpc to be equal to or higher than the threshold voltages Vth of the selector elements of all memory cells, the precharge voltage Vpc has to be set to a voltage somewhat higher than the average threshold voltage.

On the other hand, if the precharge voltage Vpc is set significantly higher than the threshold voltages Vth of the selector elements, the discharge current (i.e., the cell current) increases, which may lead to a read disturb failure. In other words, if a voltage higher than the precharge voltage Vpc originally required for the memory cells is applied, it may cause a read disturb failure. As described above, there is a trade-off between discharge failures and read disturb failures in a read operation.

In contrast to this, the first embodiment includes a constant current source CS that supplies a precharge current Ipc to the memory cell MC, and a peak detection circuit 51 that detects whether the voltage Vm of the memory cell MC has reached the threshold voltage Vth of the selector element SE, in other words, whether the voltage Vm charged to the memory cell MC (or the selector element SE) and the word line WL has risen to the threshold voltage Vth of the selector element SE.

With this configuration, the peak detection circuit 51 detects the timing at which the voltage Vm of the memory cell MC has reached the threshold voltage Vth of the selector element SE (the timing will be hereinafter referred to as threshold reaching timing). The control circuit 13 transitions the precharge switch S1 to the decoupled state at the threshold reaching timing, stopping the supply of the precharge current Ipc. This prevents excess precharge current Ipc from being supplied to the memory cell MC. This also prevents the voltage Vm of the memory cell MC from exceeding the threshold voltage Vth.

In the first embodiment, the voltage Vm charged to the memory cell MC can be set to the threshold voltage Vth of the selector element SE of that memory cell MC. In other words, the precharge voltage Vpc (i.e., the voltage Vm) can be set to be the threshold voltage Vth of each selector element SE in accordance with the variation in the threshold voltages Vth of the selector elements SE of the memory cells MC.

This eliminates the need to set the precharge voltage Vpc to a level significantly higher than the average threshold voltage, thereby reducing the occurrence of discharge failures where no discharge current (cell current) flows through the memory cell MC.

Furthermore, since a voltage higher than the precharge voltages Vpc originally required for the memory cells MC can be prevented from being applied, an increase in the cell current flowing through the variable resistance elements (e.g., MTJ elements) VR of the memory cells MC can be suppressed, and the occurrence of read disturbance failures can be reduced.

In addition, in the first embodiment, the cumulative amount of current flowing to the variable resistance element VR can be reduced as described above, so that the current load on the variable resistance element VR can be reduced in the read operation, and the lifespan of the variable resistance element VR can be extended until it becomes worn out.

Furthermore, in the read operation of the first embodiment, the discharge current (cell current) is stopped midway during discharge after the memory cell MC (and the word line WL) has been charged to the precharge voltage Vpc and then reading is performed. This enables the read operation to be completed in a shorter time compared to the case where the discharge current is not stopped and the voltage of the memory cell MC is made to reach the hold voltage Vh before reading.

As described above, the magnetic memory device 1 of the first embodiment can improve the operating performance.

### 2. SECOND EMBODIMENT

Next, a magnetic storage device of a second embodiment will be described. In the second embodiment, the signal O1 output from the peak detection circuit 51 is input to the control terminal of the precharge switch S1 to control the open/closed state of the precharge switch S1. In the second embodiment, the configuration of the memory system, the circuit configuration of the memory cell array, and the structure of the memory cell array are similar to those in the first embodiment. In connection with the second embodiment, differences from the first embodiment will mainly be described.

### 2.1 Configuration of Magnetic Memory Device

### 2.1.1 Circuit Configuration of Read Circuit

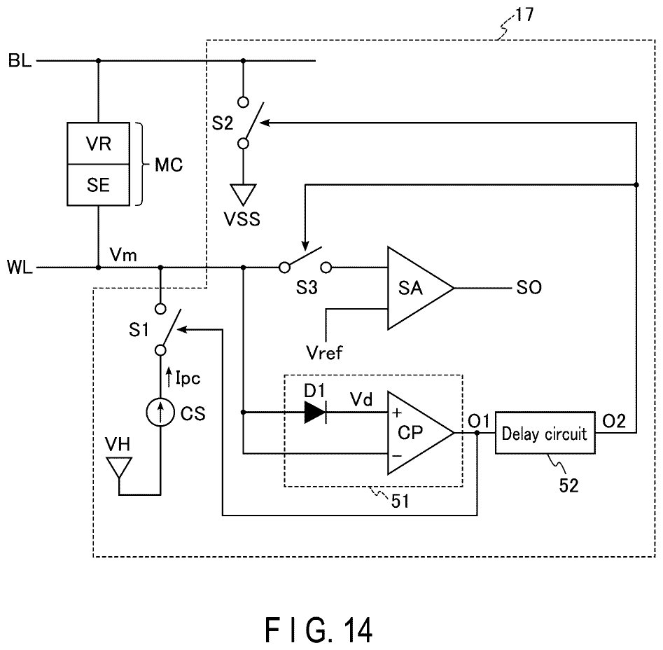

An example of a circuit configuration of a read circuit 17 included in the magnetic memory device 1 of the second embodiment will be described with reference to FIG. 14. FIG. 14 is a circuit diagram showing the configuration of the read circuit 17 of the second embodiment.

As shown in FIG. 5, in the read circuit 17 of the second embodiment, the output terminal of the comparator CP of the peak detection circuit 51 is coupled to the control terminal of the precharge switch S1. That is, the signal O1 output from the comparator CP is input to the control terminal of the precharge switch S1. The other configurations are similar to those of the read circuit 17 of the first embodiment.

### 2.2 Read Operation of Magnetic Memory Device

The read operation of the magnetic memory device 1 of the second embodiment will be described with reference to FIG. 9.

First, the read circuit 17 causes a constant current source CS to supply a precharge current Ipc to a memory cell MC (S1). The voltage Vm of the memory cell MC rises due to the supply of the precharge current Ipc, and the voltage Vm of the memory cell MC reaches the threshold voltage Vth of a selector element SE. The read circuit 17 detects that the voltage Vm of the memory cell MC has reached the threshold voltage Vth of the selector element SE (S2). The processes performed up to this point in time are similar to those of the first embodiment.

Next, when the peak detection circuit 51 detects that the voltage Vm of the memory cell MC has reached the threshold voltage Vth, the read circuit 17 stops the supply of the precharge current Ipc to the memory cell MC in response to that detection (S3).

Specifically, the signal O1 output from the comparator CP of the peak detection circuit 51 is input to the control terminal of the precharge switch S1. When the precharge switch S1 receives the signal O1 at “H,” it transitions from the coupled state to the decoupled state. The sink switch S2 and the sense amplifier switch S3 are maintained in the coupled state.

As a result, the supply of the precharge current Ipc to the memory cell MC is stopped, and the cell current Im flows from the memory cell MC and the word line WL to a ground voltage node via the sink switch S2. The voltage Vm of the memory cell MC drops below the threshold voltage Vth due to the snapback characteristic, and further drops as the cell current Im flows.

Next, as in the first embodiment, the read circuit 17 stops the cell current flowing from the memory cell MC and the word line WL after a predetermined delay time Dt has elapsed since detecting that the voltage Vm of the memory cell MC has reached the threshold voltage Vth (S4). Then, the read circuit 17 performs a read operation for the memory cell MC (S5).

### 2.3 Modification

Next, a magnetic memory device according to a modification of the second embodiment will be described. In the modification, the peak detection circuit 51 has a configuration that takes into account the forward voltage drop in the diode D1.

### 2.3.1 Circuit Configuration of Read Circuit

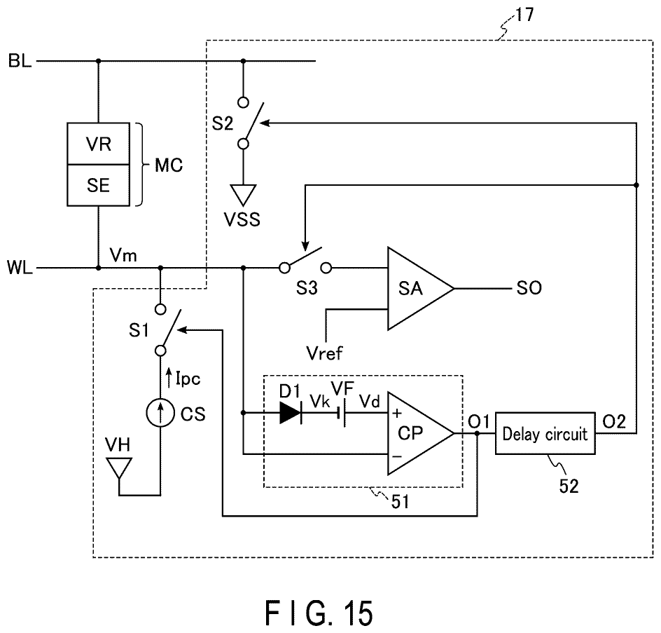

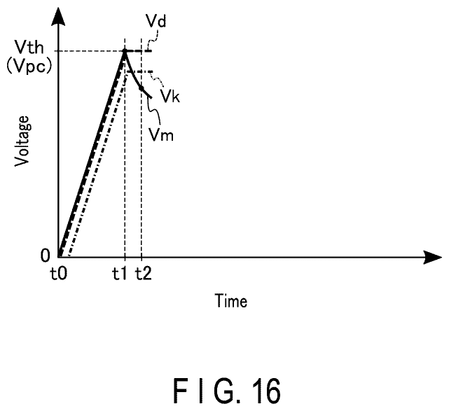

With reference to FIGS. 15 and 16, a description will be given of an example of the circuit configuration of the read circuit 17 included in a magnetic memory device 1 according to the modification of the second embodiment. FIG. 15 is a circuit diagram showing the configuration of the read circuit 17 according to the modification. FIG. 16 is a graph showing voltage changes in the voltage Vm of the memory cell MC and the voltages Vk and Vd of the diode D1 in the read operation of the magnetic memory device 1 according to the modification.

It is assumed here that a voltage drop Vf occurs in the diode D1 as a forward voltage drop. In order to compensate for this voltage drop Vf, the peak detection circuit 51 of the modification is configured such that a constant voltage source VF is arranged between the cathode of the diode D1 and the positive input terminal of the comparator CP, as shown in FIG. 15. The constant voltage source VF generates a voltage equivalent to the voltage Vf of the voltage drop in the diode D1. Let it be assumed that the voltage between the cathode of the diode D1 and the constant voltage source VF is Vk, and the voltage between the constant voltage source VF and the positive input terminal of the comparator CP is Vd.

The voltage Vm of the memory cell MC is input to the anode of the diode D1. The diode D1 lowers the voltage Vm by the voltage Vf and outputs the voltage Vk from the cathode of the diode D1. The voltage Vk output from the diode D1 is increased by the voltage Vf by the constant voltage source VF and input to the positive input terminal of the comparator CP as a voltage Vd. Thus, as shown in FIG. 16, the voltage Vd input to the positive input terminal of the comparator CP is at the same level as the voltage Vm of the memory cell MC until the voltage Vm reaches the threshold voltage Vth.

The other circuit configurations and aspects of the read operation are similar to those of the second embodiment described above.

### 2.4 Advantages of Second Embodiment

The magnetic memory device 1 of the second embodiment is advantageous in that discharge failures and read disturb failures in a read operation can be reduced and the operating performance can be improved, as in the first embodiment.

The second embodiment provides advantages described below, in addition to the above-mentioned advantages of the first embodiment.

In the configuration of the second embodiment, the signal O1 output from the comparator CP of the peak detection circuit 51 is input to the control terminal of the precharge switch S1. The signal O1 switches between the coupled state and the decoupled state of the precharge switch S1. Therefore, in the second embodiment, the circuit for controlling the precharge switch S1 can be simplified compared to that of the first embodiment.

Furthermore, in the configuration of the modification, the forward voltage drop of the diode D1 can be compensated for, so that a circuit configuration that is more suitable for implementation can be provided.

### 3. OTHERS

In the present specification, the term “coupling” means that elements are electrically coupled to each other, and does not exclude the case where another element is interposed in between. The nonmagnetic layer 41 may be referred to as an “oxide layer.” The elements contained in each layer of the MTJ element can be measured, for example, by electron energy loss spectroscopy (EELS) using a scanning transmission electron microscope (STEM).

While certain embodiments have been described, these embodiments have been presented by way of example only, and are not intended to limit the scope of the embodiments. Indeed, these embodiments can be modified in a variety of other forms; furthermore, various omissions, substitutions and changes in the form of the embodiments described herein may be made without departing from the spirit of the invention. The accompanying claims and their equivalents are intended to cover such forms or modifications as would fall within the scope and spirit of the invention.

What is claimed is:

1. A magnetic memory device comprising:
a memory cell including a variable resistance element and a selector element;
a current source configured to supply a first current to the memory cell;
a first switch coupled between the memory cell and the current source;
a second switch coupled between the memory cell and a ground voltage node to which a ground voltage is supplied;
a detection circuit including a comparator and a diode, in which a first voltage charged to the memory cell is input to a first input terminal of the comparator via the diode, and the first voltage is input to a second input terminal of the comparator;
a sense amplifier configured to compare the first voltage charged to the memory cell and a second voltage; and
a third switch coupled between the memory cell and the sense amplifier.

2. The magnetic memory device according to claim 1, wherein the detection circuit is configured to output a first signal in a case where a voltage input to the first input terminal is higher than the first voltage input to the second input terminal.

3. The magnetic memory device according to claim 2, wherein the selector element is configured to transition to a coupled state in a case where the first voltage rises to a threshold voltage, and
the first voltage drops to a voltage lower than the threshold voltage after rising to the threshold voltage.

4. The magnetic memory device according to claim 3, wherein the detection circuit is configured to detect that the first voltage drops to the voltage lower than the threshold voltage after rising to the threshold voltage, and output the first signal.

5. The magnetic memory device according to claim 2, wherein, in a case where the detection circuit outputs the first signal, the first switch is configured to decouple the memory cell and the current source from each other.

6. The magnetic memory device according to claim 2, wherein an output terminal of the detection circuit is electrically coupled to the first switch,
in a case where the first signal is output from the detection circuit, the first switch is configured to decouple the memory cell and the current source from each other in response to the first signal.

7. The magnetic memory device according to claim 1, further comprising a delay circuit electrically coupled to an output terminal of the detection circuit,
wherein an output terminal of the delay circuit is electrically coupled to the second switch and the third switch,
the detection circuit is configured to output a first signal in a case where a voltage input to the first input terminal is higher than the first voltage input to the second input terminal, and
the delay circuit is configured to delay the first signal by a first delay time and output a second signal to the second switch and the third switch.

8. The magnetic memory device according to claim 1, further comprising:
a first interconnect coupled to one end of the memory cell; and
a second interconnect coupled to another end of the memory cell,
wherein the first voltage is a voltage that is intermediate between the first interconnect and the second interconnect.

9. The magnetic memory device according to claim 1, further comprising:
a first interconnect coupled to one end of the memory cell; and
a second interconnect coupled to another end of the memory cell,
wherein one end of the selector element is coupled to the first interconnect,
the first current is supplied from the current source to the first interconnect, and
the first voltage is a voltage held by the first interconnect.

10. The magnetic memory device according to claim 1, wherein the variable resistance element includes a magnetic tunnel junction (MTJ) element.

11. A magnetic memory device comprising:
a memory cell including a variable resistance element and a selector element;
a current source configured to supply a first current to the memory cell;
a first switch coupled between the memory cell and the current source;
a second switch coupled between the memory cell and a ground voltage node to which a ground voltage is supplied;
a detection circuit configured to output a first signal in a case where a second current flows from the memory cell to the second switch;
a sense amplifier configured to compare a first voltage charged to the memory cell with a second voltage; and
a third switch coupled between the memory cell and the sense amplifier.

12. The magnetic memory device according to claim 11, wherein the second current flows in a case where the selector element is set to a coupled state.

13. The magnetic memory device according to claim 11, wherein the selector element has a threshold voltage, and
the second current flows when the first voltage of the memory cell rises to the threshold voltage.

14. The magnetic memory device according to claim 11, wherein the selector element is configured to transition to a coupled state in a case where the first voltage rises to a threshold voltage, and
the first voltage drops to a voltage lower than the threshold voltage after rising to the threshold voltage.

15. The magnetic memory device according to claim 14, wherein the detection circuit is configured to detect that the first voltage drops to the voltage lower than the threshold voltage after rising to the threshold voltage, and output the first signal.

16. The magnetic memory device according to claim 11, wherein the detection circuit includes a comparator and a diode, in which the first voltage is input to a first input terminal of the comparator via the diode, and the first voltage is input to a second input terminal of the comparator.

17. The magnetic memory device according to claim 11, wherein in a case where the detection circuit outputs the first signal, the first switch is configured to decouple the memory cell and the current source from each other.

18. The magnetic memory device according to claim 11, wherein an output terminal of the detection circuit is electrically coupled to the first switch, and
in a case where the first signal is output from the detection circuit, the first switch is configured to decouple the memory cell and the current source from each other in response to the first signal.

19. The magnetic memory device according to claim 11, further comprising a delay circuit electrically coupled to an output terminal of the detection circuit,
wherein an output terminal of the delay circuit is electrically coupled to the second switch and the third switch,
the detection circuit is configured to output the first signal to the delay circuit, and
the delay circuit is configured to delay the first signal by a first delay time and output a second signal to the second switch and the third switch.

20. The magnetic memory device according to claim 11, further comprising:
a first interconnect coupled to one end of the memory cell; and
a second interconnect coupled to another end of the memory cell,
wherein the first voltage is a voltage that is intermediate between the first interconnect and the second interconnect.
